(19) United States
(12) Patent Application Publication
(10) Pub. No.: US 2026/0326100 A1
(43) Pub. Date: Oct. 22, 2026

(54) BASE FOR A MICROFLUIDIC MANIFOLD, MICROFLUIDIC MANIFOLD, AND METHOD FOR MANUFACTURING A BASE FOR A MICROFLUIDIC MANIFOLD

(71) Applicant: INTERFACE FLUIDICS LTD., CALGARY (CA)

(72) Inventors: THOMAS DE HAAS, EDMONTON (CA); DAVID O'BRIEN, EDMONTON (CA); CAMERON JAMES RANKIN, CALGARY (CA); SIMON ROBERT SCHMITT, CALGARY (CA)

(73) Assignee: INTERFACE FLUIDICS LTD., CALGARY, AB (CA)

(21) Appl. No.: 19/117,438

(22) PCT Filed: Sep. 29, 2023
(86) PCT No.: PCT/CA2023/051296

§ 371 Date: Apr. 1, 2025

Related U.S. Application Data
(60) Provisional application No. 63/413,698, filed on Oct. 6, 2022.

(51) Int. Cl. B01L 3/00; B01L 9/00

(52) U.S. Cl. CPC B01L 3/502715; B01L 9/527; B01L 2200/0689; B01L 2400/06

(57) ABSTRACT

A base for a microfluidic manifold includes a first metallic block and a second metallic block. The first metallic block has a plurality of channels formed into a first surface thereof. Each channel is in fluid communication with a respective fluid inlet/outlet port of the first metallic block. The second metallic block overlies and is bonded to the first surface of the first metallic block to cover the plurality of channels. The second metallic block has a plurality of conduits that extend therethrough towards the first metallic block. A microfluidic chip is seatable against the second metallic block, and the conduits provide fluid communication between the microfluidic chip and the plurality of channels.

### CROSS REFERENCES TO RELATED APPLICATIONS

This application claims priority to U.S. Provisional Patent Application No. 63/413,698 filed on Oct. 6, 2022, which is incorporated herein by reference in its entirety.

### FIELD

This document relates to microfluidics. More specifically, this document relates to manifolds for microfluidic chips, and related parts, methods, and assemblies.

### BACKGROUND

International Patent Application Publication No. WO 2020/037398 A1 (De Haas et al.) discloses a holder for a microfluidic chip that includes a base having an outward facing surface, a seat defined in the outward facing surface for receiving a microfluidic chip, and a first circular wall extending around the seat and having a first screw thread. A cover is mountable to the base over the seat for retaining the microfluidic chip on the seat. The cover has a window and a second circular wall extending around the window. The second circular wall has a second screw thread. The second screw thread is engageable with the first screw thread to screw the cover to the base with the window overlying the seat.

### SUMMARY

The following summary is intended to introduce the reader to various aspects of the detailed description, but not to define or delimit any invention.

Bases for microfluidic manifolds are disclosed. According to some aspects, a base for a microfluidic manifold includes a first metallic block having a plurality of channels formed into a first surface thereof. Each channel is in fluid communication with a respective fluid inlet/outlet port of the first metallic block. The base further includes second metallic block against which a microfluidic chip is seatable. The second metallic block overlies and is bonded to the first surface of the first metallic block to cover the plurality of channels. The second metallic block has a plurality of conduits that extend therethrough towards the first metallic block, for providing fluid communication between the microfluidic chip and the plurality of channels.

In some examples, the first metallic block further includes at least a first valve port. The first valve port may provide fluid communication between a first one of the conduits and a first one of the fluid inlet/outlet ports. A first valve may be received in the first valve port. The first valve may be moveable between an open configuration in which the first one of the conduits and the first one of the fluid inlet/outlet ports are in fluid communication via the first valve port, and a closed configuration in which fluid communication between the first one of the conduits and the first one of the fluid inlet/outlet ports is prevented. When the microfluidic chip is seated against the second metallic block and the first valve is in the closed configuration, a dead space may be defined in the base between the valve and the microfluidic chip, and the dead space may have a volume of at most 10 microlitres.

In some examples, the first metallic block further includes at least a first instrument port that is in fluid communication with a first one of the channels. A first instrument may be received in the first instrument port. The first instrument may be or may include a pressure sensor, a viscosity sensor, and/or a density sensor. The first metallic block may further include a second instrument port that is in fluid communication with the first one of the channels. A second instrument may be received in the second instrument port.

In some examples, the first metallic block further includes at least one heating cartridge receptacle. A heating cartridge may be received in the heating cartridge receptacle.

In some examples, the first metallic block is diffusion bonded to the second metallic block.

In some examples, the first metallic block is a relatively thick block, and the second metallic block is a relatively thin platelet.

In some examples, the base further includes a third metallic block having a plurality of additional channels formed into a first surface thereof. Each additional channel may be in fluid communication with a respective fluid inlet/outlet port of the third metallic block. The first metallic block may overlie and be bonded to the first surface of the third metallic block to cover the plurality of additional channels. The first metallic block may have a plurality of additional conduits that extend therethrough towards the third metallic block, for providing fluid communication between the microfluidic chip and the plurality of additional channels.

Microfluidic manifold assemblies are also disclosed. According to some aspects, a microfluidic manifold assembly includes a microfluidic chip having a plurality of microfluidic inlet/outlet ports and at least a first microfluidic channel that is in fluid communication with the plurality of microfluidic inlet/outlet ports. The assembly further includes a base having a first metallic block having a plurality of channels formed into a first surface thereof. Each channel is in fluid communication with a respective fluid inlet/outlet port of the first metallic block. The base further includes a second metallic block against which the microfluidic chip is seated. The second metallic block overlies and is bonded to the first surface of the first metallic block to cover the plurality of channels. The second metallic block has a plurality of conduits extending therethrough towards the first metallic block, for providing fluid communication between the microfluidic inlet/outlet ports and the plurality of channels. The assembly further includes a cover positioned over the microfluidic chip and bearing against the microfluidic chip to sandwich the microfluidic chip between the base and the cover.

In some examples the assembly further includes at least a first seal. The microfluidic chip may be seated against the second metallic block via the first seal, and the first seal may be configured to seal at least a first one of the microfluidic inlet/outlet ports to a first one of the conduits.

In some examples, the assembly further includes a plurality of fluid lines mounted to the first metallic block. Each fluid line may be in fluid communication with a respective one of the fluid inlet/outlet ports, for delivering fluid to and/or from the microfluidic chip via the base.

In some examples, the first metallic block further includes at least a first valve port, and the base further includes a first valve received in the first valve port. The valve may be moveable between an open configuration in which a first one of the conduits and a first one of the fluid inlet/outlet ports are in fluid communication via the first valve port, and a closed configuration in which fluid communication between the first one of the conduits and the first one of the fluid inlet/outlet ports is prevented. When the valve is in the closed configuration, a dead space may be defined in the base between the valve and a first one of the microfluidic inlet/outlet ports. The dead space may have a volume of at most 10 microlitres.

In some examples, the first metallic block further includes at least a first instrument port that is in fluid communication with a first one of the channels, and the base further includes a first instrument received in the first instrument port. The instrument may be or may include a pressure sensor, a viscosity sensor, and/or a density sensor. The first metallic block may further include a second instrument port in fluid communication with the first one of the channels, and the base may further include a second instrument received in the second instrument port.

In some examples, the first metallic block further includes a heating cartridge receptacle, and a heating cartridge received in the heating cartridge receptacle.

In some examples, the first metallic block is diffusion bonded to the second metallic block.

In some examples, the first metallic block is a relatively thick block, and the second metallic block is a relatively thin platelet.

In some examples, at least one of the base and the cover includes a viewing window aligned with the microfluidic chip for allowing optical access to the microfluidic chip.

In some examples, the base further includes a third metallic block having a plurality of additional channels formed into a first surface thereof. Each additional channel may be in fluid communication with a respective fluid inlet/outlet port of the third metallic block. The first metallic block may overlie and be bonded to the first surface of the third metallic block to cover the plurality of additional channels. The first metallic block may have a plurality of additional conduits that extend therethrough towards the third metallic block, for providing fluid communication between the microfluidic chip and the plurality of additional channels.

Methods for manufacturing a base for a microfluidic manifold are disclosed. According to some aspects, a method of manufacturing a base for a microfluidic manifold includes: a. forming a plurality of channels into a first surface of a first metallic block; b. after step a., bonding a second metallic block to the first surface to cover the plurality of channels; c. forming a plurality of conduits through the second metallic block, whereby the plurality of conduits are in fluid communication with the plurality of channels; and d. forming a plurality of fluid inlet/outlet ports in the first metallic block, whereby the plurality of fluid inlet/outlet ports are in fluid communication with the plurality of channels.

In some examples, step a. includes ball milling the plurality of channels into the first surface of the first metallic block. In some examples, step a. includes acid etching the plurality of channels into the first surface of the first metallic block.

In some examples, step b. includes diffusion bonding the second metallic block to the first metallic block.

In some examples, step c. includes machining the plurality of conduits into the second metallic block.

In some examples, step d. includes machining the fluid inlet/outlet ports into the first metallic block.

In some examples, step c. and step d. are carried out after step b.

In some examples, the method further includes forming at least a first valve port in the first metallic block, whereby a first one of the conduits and a first one of the fluid inlet/outlet ports are in fluid communication via the first valve port.

In some examples, the method further includes forming at least a first instrument port in the first metallic block, whereby the first instrument port is in fluid communication with the first channel.

In some examples, the method further includes bonding a third metallic block to the first metallic block. The third metallic block may have a plurality of additional channels formed into a first surface thereof and each additional channel may be in fluid communication with a respective fluid inlet/outlet port of the third metallic block. The first metallic block may be bonded to the third metallic block to cover the plurality of additional channels. The first metallic block may have a plurality of additional conduits that extend therethrough towards the third metallic block, for providing fluid communication between the microfluidic chip and the plurality of additional channels.

### BRIEF DESCRIPTION OF THE DRAWINGS

The drawings included herewith are for illustrating various examples of articles, methods, and apparatuses of the present specification and are not intended to limit the scope of what is taught in any way. In the drawings:

FIG. 1 is an exploded perspective view of an example microfluidic chip and example base for a microfluidic manifold;

FIG. 2 is a top plan view of the base of FIG. 1, showing various internal features in dotted line;

FIG. 3 is a partial perspective view of the seat of the base of FIGS. 1 and 2;

FIG. 4 is a perspective view of a first metallic block of the base of FIGS. 1 to 3, in an intermediate stage of manufacture;

FIG. 5 is a perspective view of a second metallic block of the base of FIGS. 1 to 3, in an intermediate stage of manufacture;

FIG. 6 is an exploded perspective view of the first metallic block of FIG. 4 and the second metallic block of FIG. 5, showing the alignment of the parts for bonding;

FIG. 7 is a perspective view of the first metallic block of FIG. 4 and the second metallic block of FIG. 5, showing the parts bonded together;

FIG. 8 is a perspective view of an assembly including the base of FIGS. 1 to 3, the microfluidic chip of FIG. 1 seated against the base, valves received in the valve ports of the base, fluid line connectors received in the fluid inlet/outlet ports of the base, and instruments received in the instrument ports of the base;

FIG. 9a is a cross-section taken along line 9a-9a in FIG. 2;

FIG. 9b is a cross-section taken along line 9b-9b in FIG. 2;

FIG. 10 is a perspective view of microfluidic manifold including the base of the base of FIGS. 1 to 3, with the microfluidic chip of FIG. 1 seated against the base, with valves received in the valve ports of the base, with fluid line connectors received in the fluid inlet/outlet ports of the base, and with instruments received in the instrument ports of the base.

### DETAILED DESCRIPTION

Various apparatuses or processes or compositions will be described below to provide an example of an embodiment of the claimed subject matter. No embodiment described below limits any claim and any claim may cover processes or apparatuses or compositions that differ from those described below. The claims are not limited to apparatuses or processes or compositions having all of the features of any one apparatus or process or composition described below or to features common to multiple or all of the apparatuses or processes or compositions described below. It is possible that an apparatus or process or composition described below is not an embodiment of any exclusive right granted by issuance of this patent application. Any subject matter described below and for which an exclusive right is not granted by issuance of this patent application may be the subject matter of another protective instrument, for example, a continuing patent application, and the applicants, inventors or owners do not intend to abandon, disclaim or dedicate to the public any such subject matter by its disclosure in this document.

For simplicity and clarity of illustration, reference numerals may be repeated among the figures to indicate corresponding or analogous elements. In addition, numerous specific details are set forth in order to provide a thorough understanding of the subject matter described herein. However, it will be understood by those of ordinary skill in the art that the subject matter described herein may be practiced without these specific details. In other instances, well-known methods, procedures and components have not been described in detail so as not to obscure the subject matter described herein. The description is not to be considered as limiting the scope of the subject matter described herein.

The terms “coupled” or “coupling” as used herein can have several different meanings depending on the context in which these terms are used. For example, the terms coupled or coupling can have a mechanical, electrical or communicative connotation. For example, as used herein, the terms coupled or coupling can indicate that two elements or devices are directly connected to one another or connected to one another through one or more intermediate elements or devices via an electrical element, electrical signal, or a mechanical element depending on the particular context.

As used herein, the wording “and/or” is intended to represent an inclusive-or. That is, “X and/or Y” is intended to mean X or Y or both, for example. As a further example, “X, Y, and/or Z” is intended to mean X or Y or Z or any combination thereof. Furthermore, the wording “at least one of A and B” is intended to mean only A (i.e. one or multiple of A), only B (i.e. one or multiple of B), or a combination of one or more of A and one or more of B.

Terms of degree such as “substantially”, “about”, and “approximately” as used herein mean a reasonable amount of deviation of the modified term such that the end result is not significantly changed. These terms of degree may also be construed as including a deviation of the modified term if this deviation would not negate the meaning of the term it modifies.

Any recitation of numerical ranges by endpoints herein includes all numbers and fractions subsumed within that range (e.g. 1 to 5 includes 1, 1.5, 2, 2.75, 3, 3.90, 4, and 5). It is also to be understood that all numbers and fractions thereof are presumed to be modified by the term “about” which means a variation of up to a certain amount of the number to which reference is being made if the end result is not significantly changed.

Generally disclosed herein are microfluidic manifolds (also referred to as ‘holders’ or simply as ‘manifolds’), and related methods, assemblies, and parts. The manifolds can generally serve to hold a microfluidic chip, and to direct fluid into and out of the microfluidic chip, while allowing for optical access to the microfluidic chip (e.g. for the purpose of assessing the flow of fluids through the microfluidic chip). The manifolds generally include a base, against which a microfluidic chip is seatable, and a cover. The base and the cover can be forced together with the microfluidic chip sandwiched therebetween. By forcing the base and the cover together with the microfluidic chip sandwiched therebetween, the microfluidic inlet/outlet ports of the microfluidic chip are sealed to the base. Fluids can then be routed through the base and into the microfluidic chip. While the fluids are flowing through the microfluidic chip, an optical investigation can be conducted via a viewing window (e.g. in the cover), to assess the fluids. Examples of such manifolds are described in International Patent Application Publication No. WO/2020/037398 (de Haas et al.), U.S. Pat. No. 11,391,393 (Sinton et al.), and International Patent Application Publication No. WO2022/251951 (de Haas et al.), each of which is incorporated herein by reference in its entirety.

In the manifolds disclosed herein, the base of the manifold is configured to allow for relatively complex fluid pathways therethrough, which in turn allows for various sensors and valves to be coupled directly to the base (as opposed to being coupled to external components such as tubing). For example, pressure sensors, viscosity sensors, and density sensors can be coupled directly to the base, to measure the parameters of the fluid flowing through the base. Optionally, a relatively large number of sensors can be coupled directly to the base. Furthermore, valves can be coupled directly to the base, to control fluid flow through the base. The base can provide the manifold with a relatively small footprint, and can allow for relatively small fluid volumes to be routed through the base to and/from a microfluidic chip (e.g. fluid volumes of as low as about 50 microlitres). Furthermore, the base can provide the manifold with a relatively low dead volume (e.g. a dead volume of less than 8 microlitres). Furthermore, the base can provide relatively consistent temperature control.

In order to allow relatively complex fluid pathways therethrough, the base generally includes a plurality of layers in the form of metallic blocks. That is, the base can include a first metallic block, a second metallic block, and so on. In some examples, the base may include only a first metallic block and a second metallic block; however, in other examples, the base may include more than two metallic blocks (i.e. three or more metallic blocks, such as dozens of metallic blocks). A plurality of channels can be formed into a surface of the first metallic block, for example by etching or ball-milling. The second metallic block can then be bonded to the first metallic block (e.g. by diffusion bonding), such that it overlies the first metallic block and covers the plurality of channels. A plurality of conduits can be formed through the second metallic block, to provide fluid communication between the surface of the second metallic block and the plurality of channels, and a plurality of valve ports and/or instrument ports can be formed into the first metallic block (e.g. by machining), to allow for valves and/or instruments (e.g. sensors) to be coupled to the channels. A microfluidic chip can then be seated against the second metallic block, with the microfluidic inlet/outlet ports thereof aligned with the conduits, to allow for fluid communication between the microfluidic inlet/outlet ports and the channels.

The base and related manifolds, assemblies, and parts disclosed herein can in some examples be used under high pressure conditions. That is, the base, microfluidic chip, and cover can be forced together under high pressure (e.g. using a jack). This creates a high-pressure seal between the base and the microfluidic chip. Furthermore, this compresses the microfluidic chip, to apply a high confining pressure to the microfluidic chip. The high confining pressure allows for fluids to be directed through the base and into the microfluidic chip under high pressure (e.g. with fluids pressurized to greater than 300 bar, for example up to 700 bar) without bursting the microfluidic chip (or while reducing or minimizing the risk of bursting the microfluidic chip), as the confining pressure opposes the forces applied to the microfluidic chip when fluids are directed into the microfluidic chip under high pressure. The base and related manifolds, parts, and assemblies can be used in various types of microfluidic processes and to hold various types of microfluidic chips, but may be particularly useful in microfluidic research in the oil and gas industry, such as research involving the modelling of subterranean formations (e.g. oil-bearing shale formations), research involving PVT measurements of oil and/or gas samples, and/or research involving phase behavior of oil and/or gas samples, all of which can require that high pressure conditions be created in a microfluidic chip.

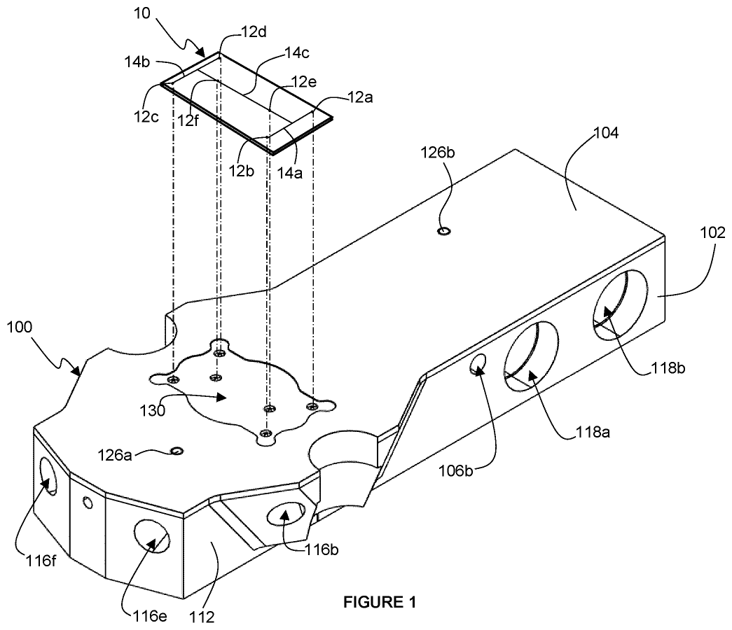

Various microfluidic chips can be used with the base and related manifolds, parts, and assemblies disclosed herein. Examples are disclosed in U.S. Pat. No. 11,285,476 (Abedini et al.), U.S. Pat. No. 10,001,435 (Sinton et al.), International Patent Application Publication No. WO2021/253112 (Ahitan et al.), International Patent Application Publication No. WO2022/126252 (Ahitan et al.), and International Patent Application No. PCT/CA2023/050979 (Soni et al.). In general, a microfluidic chip usable with the base, manifolds, parts, and assemblies disclosed herein may include a plurality of microfluidic inlet/outlet ports (i.e. at least one port that can serve as a microfluidic inlet, and at least one port that can serve as a microfluidic outlet), and at least a first microfluidic channel that is in fluid communication with the plurality of microfluidic inlet/outlet ports. An example of one such microfluidic chip 10 is shown in FIG. 1. The microfluidic chip 10 includes six microfluidic inlet/outlet ports 12a-f (i.e. a first microfluidic inlet/outlet port 12a, a second microfluidic inlet/outlet port 12b, and so on), and a set of microfluidic channels 14a-c that are in fluid communication with the plurality of microfluidic inlet/outlet ports 12a-f.

Referring still to FIG. 1, an example base 100 for a microfluidic manifold is shown, together with microfluidic chip 10. As described above, in use, when assembled in a manifold, the microfluidic chip 10 can be seated against the base 100 and sandwiched between the base 100 and a cover (not shown in FIG. 1). This seals the microfluidic chip to the base 100, and the base 100 can then be used to route fluids to and/or from the microfluidic chip 10.

Referring still to FIG. 1, the base 100 generally includes a first metallic block 102, and a second metallic block 104. In the example shown, the first metallic block 102 is a relatively thick block and the second metallic block 104 is a relatively thin platelet. In alternative examples, the metallic blocks may be of another configuration. For example, the second metallic block may be relatively thick. In further alternative examples, the base may include additional metallic blocks (e.g. a third metallic block, and optionally a fourth or further metallic blocks), as described in further detail below.

The metallic blocks 102 and 104 may be or may include, for example, stainless steel (e.g. duplex stainless steel), a nickel alloy (e.g. an austenitic nickel-chromium-based superalloy), titanium and alloys thereof, and/or other corrosion resistant alloys.

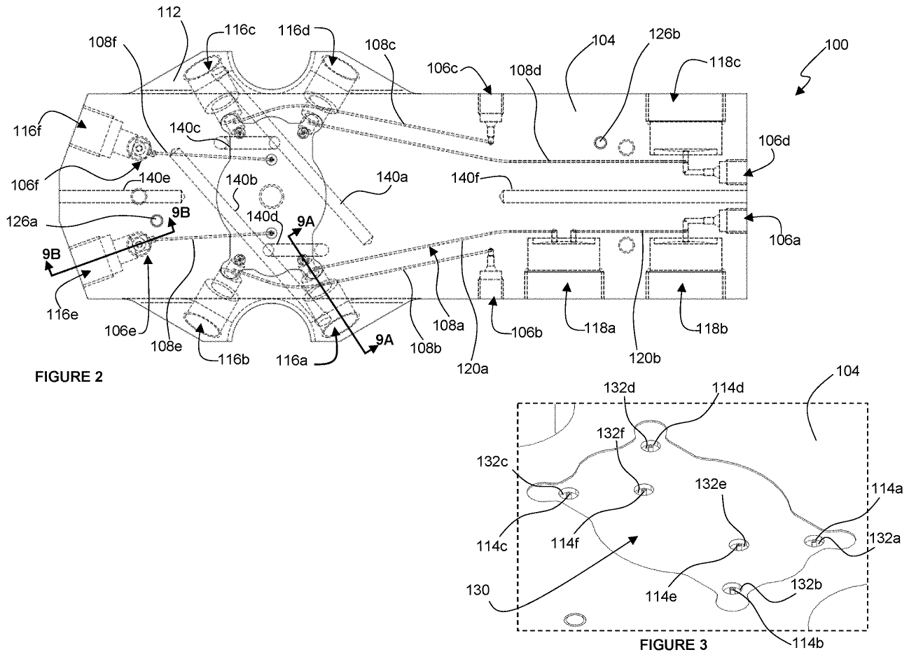

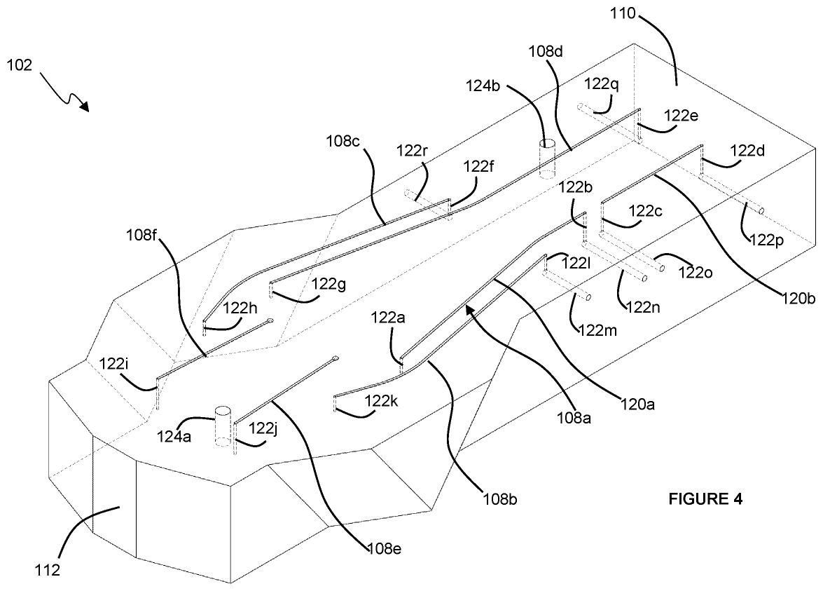

As can be seen in FIG. 2, and as will be described in further detail below, the first metallic block 102 (not labelled in FIG. 2) has a plurality of fluid inlet/outlet ports 106a-f (i.e. a first fluid inlet/outlet 106a, a second fluid inlet/outlet 106b, and so on), and a plurality of channels 108a-f (i.e. a first channel 108a, a second channel 108b, and so on) formed into a first surface 110 thereof (also referred to as a “top surface”, shown in FIG. 4). In the example shown, the first through fourth fluid inlet/outlet ports 106a-d are in a side surface 112 of the first metallic block 102, while the fifth 106e and sixth 106f are in a bottom surface (not shown) of the first metallic block 102. Each channel 108a-f is in fluid communication with a respective one of the fluid inlet/outlet ports 106a-f, Furthermore, as will be described in further detail below, the second metallic block 104 overlies and is bonded to the first surface 110 of the first metallic block 102, to cover the plurality of channels 108a-f, As can be seen in FIG. 3, the second metallic block 104 has a plurality of conduits 114a-f (i.e. a first conduit 114a, a second conduit 114b, and so on) that extend therethrough, towards and into the first metallic block 102. When the microfluidic chip 10 is seated against the second metallic block 104, the conduits 114a-f provide fluid communication between the microfluidic inlet/outlet ports 12a-f of the microfluidic chip and the plurality of channels 108a-f, Furthermore, as can be seen in FIG. 2 and as will be described in further detail below, the first metallic block 102 further includes a plurality of valve ports 116a-f (i.e. a first valve port 116a, a second valve port 116b, and so on) that are in fluid communication with the channels 108a-f; and a plurality of instrument ports 118a-c (i.e. a first instrument port 118a, a second instrument port 118b, and a third instrument port 118c) that are in fluid communication with the channels 108a and 108d. A respective valve can be received in each valve port 116a-f, and the valves can be actuated to control fluid flow through the base 100. A respective instrument (e.g. a sensor) can be received in each instrument port 118a-c, for sensing a parameter of the fluid in the channels 108a and 108d.

Referring now to FIGS. 4 to 8, the base will be described in further detail, together with its method of manufacture.

Referring first to FIG. 4, the first metallic block 102 is shown, prior to being bonded to the second metallic block 104 (not shown in FIG. 4). At this stage of manufacture, the first metallic block 102 includes the plurality of channels 108a-f, which have been formed into the first surface 110 thereof. For example, the plurality of channels 108a-f may be milled (e.g. ball milled and/or end milled), etched (e.g. acid etched, laser etched, chemically etched, and/or water-jet etched), and/or electro-discharge machined into the first surface 110 of the first metallic block 102. At this stage, the first channel 108a is separated into two channel sections 120a, 120b, which will be joined in fluid communication in a later manufacturing stage.

The channels 108a-f may be of a variety of configurations. For example, the channels may be straight, curved, serpentine, and/or branched. The channels may be of various depths. Furthermore, various numbers of channels are possible.

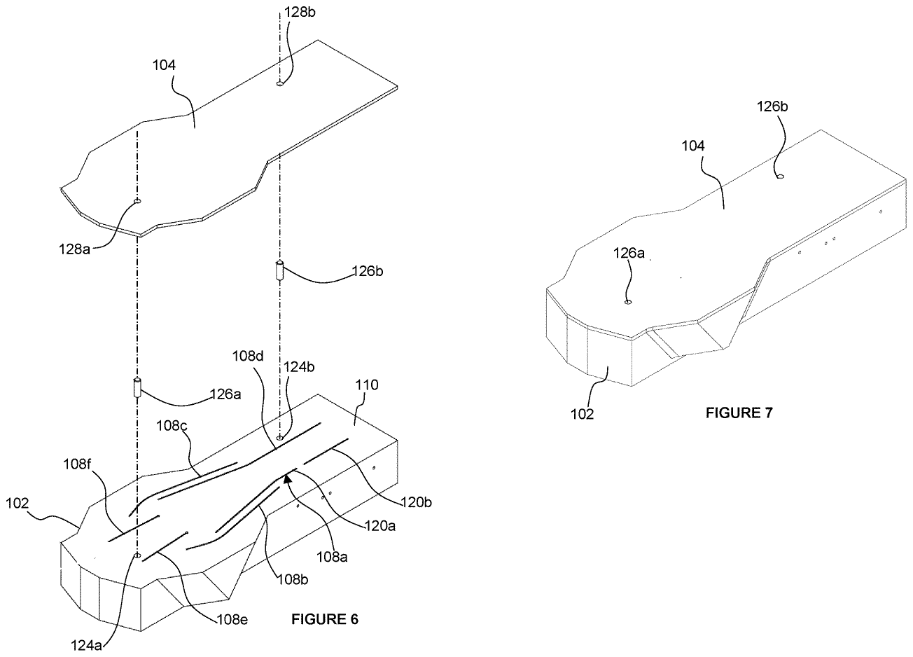

Referring still to FIG. 4, the first metallic block 102 further includes a plurality of bores 122a-r (i.e. a first bore 122a, a second bore 122b, and so on, shown in dotted line), which extend into the first metallic block 102 from various surfaces thereof. Each bore 122a-r is in fluid communication with one of the channels 108a-f, The first metallic block 102 further includes a pair of holes 124a-b for alignment pins 126a-b (shown in FIG. 6).

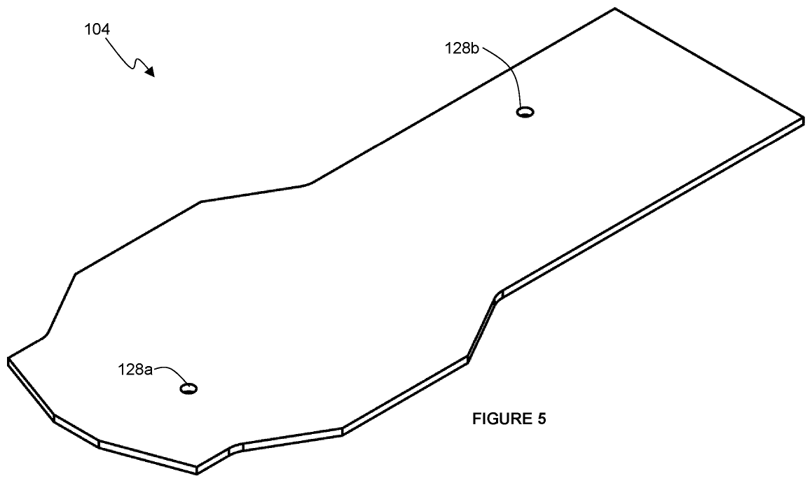

Referring now to FIG. 5, the second metallic block 104 is shown, prior to being bonded to the first metallic block 102. At this stage of manufacture, the second metallic block 104 is generally shaped to match the shape of the first metallic block 102, and includes its own pair of holes 128a-b for receipt of the alignment pins 126a-b (shown in FIG. 6).

The first metallic block 102, in the stage of manufacture as shown in FIG. 4, and the second metallic block 104, in the stage of manufacture as shown in FIG. 5, can then be joined together. In particular, as shown in FIG. 6, using the alignment pins 126a-b, the second metallic block 104 can be aligned with the first surface 110 of the first metallic block 102, such that it overlies and covers the channels 108a-f, and the second metallic block 104 can be bonded to the first surface 110 of the first metallic block 102. For example, the second metallic block 104 can be bonded to the first metallic block 102 by diffusion bonding, brazing, welding, with the use of fasteners, and/or with the use of adhesives. Preferably, the second metallic block 104 is bonded to the first metallic block 102 by diffusion bonding. The part after joining together the first metallic block 102 and second block 104 is shown in FIG. 7.

After joining together the first metallic block 102 and second metallic block 104, the part can be further machined, to yield the base 100 in its final state, as shown in FIGS. 1 to 3. In particular, referring back to FIG. 3, the conduits 114a-f can be formed through the second metallic block 104, towards and into the first metallic block 102 (e.g. by machining). The fifth 114e and sixth 114f conduits can be formed to join directly to the fifth 108e and sixth 108f channels. The first through fourth conduits 114a-d can be formed such that they are spaced from the first through fourth channels 108a-f (the first through fourth conduits 114a-f will be joined to the first through fourth channels 108a-f in a subsequent machining step, described below). Furthermore, the surface of the second metallic block 104 can be machined to include a recessed seat 130 for the microfluidic chip 10. The seat 130 can be further machined to include a plurality of annular recesses 132a-f, each of which surrounds a respective one of the conduits 114a-f, In use, seals (e.g. o-rings, not shown) can be received in the annular recesses 132a-f, and the microfluidic chip can be seated against the second metallic block 104 via the seals. The seals can seal the microfluidic inlet/outlet ports 12a-f of the microfluidic chip 10 to the conduits 114a-f when the microfluidic chip 10 is sandwiched between the base 100 and a cover of a microfluidic manifold. In alternative examples, another type of seal can be used, such as a single sheet seal that nests into the seat. Such sealing mechanisms are described in International Patent Application Publication No. WO2022/251951 (de Haas et al.), which is incorporated herein by reference in its entirety.

Referring back to FIG. 2, the instrument ports 118a-c can then be formed in the first metallic block 102 (e.g. by machining), such that they are in fluid communication with the channels 108a and 108d. In the example shown, the first instrument port 118a is formed into the first metallic block 102 at the location of bores 122n and 1220 (labelled in FIG. 4), such that the first instrument port 118a provides fluid communication between the first channel section 120a and the second channel section 120b of the first channel 108a via bores 122b and 122c (labelled in FIG. 4). The second instrument port 118b is formed into the first metallic block 102 at the location of bore 122p (labelled in FIG. 4) such that it is in fluid communication with the second channel section 120b of the first channel 108a via bore 122d (labelled in FIG. 4). The third instrument port 118c is formed into the first metallic block 102 at the location of bore 122q, such that it is in fluid communication with the fourth channel 108d via bore 122e (labelled in FIG. 4).

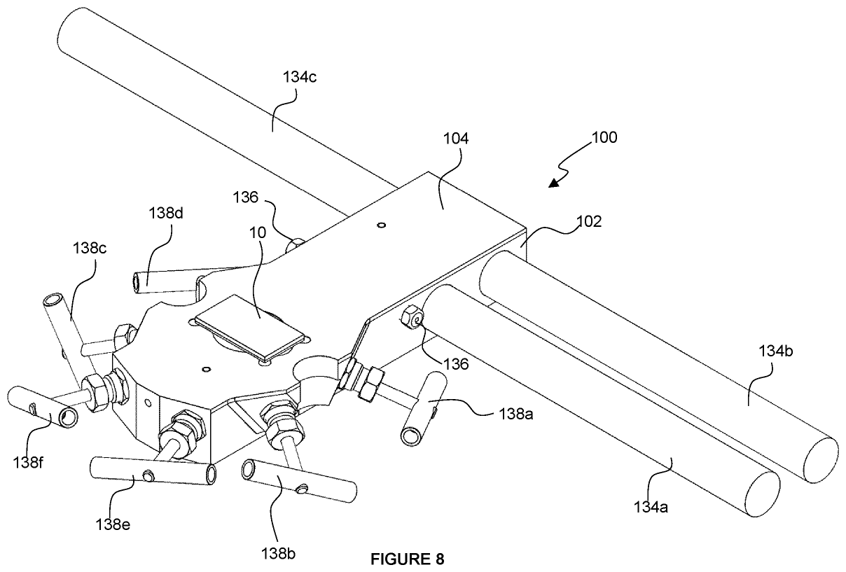

As shown in FIG. 8, various instruments 134a-c (e.g. a pressure sensor, a viscosity sensor, a density sensor a flow sensor, and/or a multi-phase spectrometry sensor) can be received in the instrument ports 118a-c (not labelled in FIG. 8) (i.e. a first instrument 134a can be received in the first instrument port 118a, a second instrument 134 can be received in the second instrument port 118b, and so on), to measure one or more parameters of the fluid flowing through the base 100.

Referring back to FIG. 2, the fluid inlet/outlet ports 106a-f can then be formed in the first metallic block 102 (e.g. by machining). The fluid inlet/outlet ports 106a-f are formed such that they are in fluid communication with the channels 108a-f, That is, the first fluid inlet/outlet port 106a is in fluid communication with the first channel 108a, the second fluid inlet/outlet port 106b is in fluid communication with the second channel 108b, and so on. In particular, the first fluid inlet/outlet port 106a is formed such that is in fluid communication with the first channel 108a via the first instrument port 118a; the second fluid inlet/outlet port 106b is formed at the location of bore 122m (labelled in FIG. 4), such that it is fluid communication with the second channel 108b via bore 1221 (labelled in FIG. 4); the third fluid inlet/outlet port 106c is formed at the location of bore 122r (labelled in FIG. 4), such that it is fluid communication with the channel 108c via bore 122f (labelled in FIG. 4); the fourth fluid inlet/outlet port 106d is formed such that is in fluid communication with the fourth channel 108d via the third instrument port 118c; the fifth fluid inlet/outlet port 106e is formed such that it is in fluid communication with the fifth channel 108e via the fifth valve port 116e, as described in further detail below; and the sixth fluid inlet/outlet port 106f is formed such that it is in fluid communication with the sixth channel 108f via the sixth valve port 116f, as described in further detail below. The fluid inlet/outlet ports 106a-f can be formed such that fluid lines (e.g. tubing, not shown) can be connected thereto. Each fluid line can be connected in fluid communication with a respective one of the fluid inlet/outlet ports 106a-f, for delivering fluid to and/or from the microfluidic chip 10 via the base 100. FIG. 8 shows fluid line connectors 136 received in the fluid inlet/outlet ports 106b and 106c.

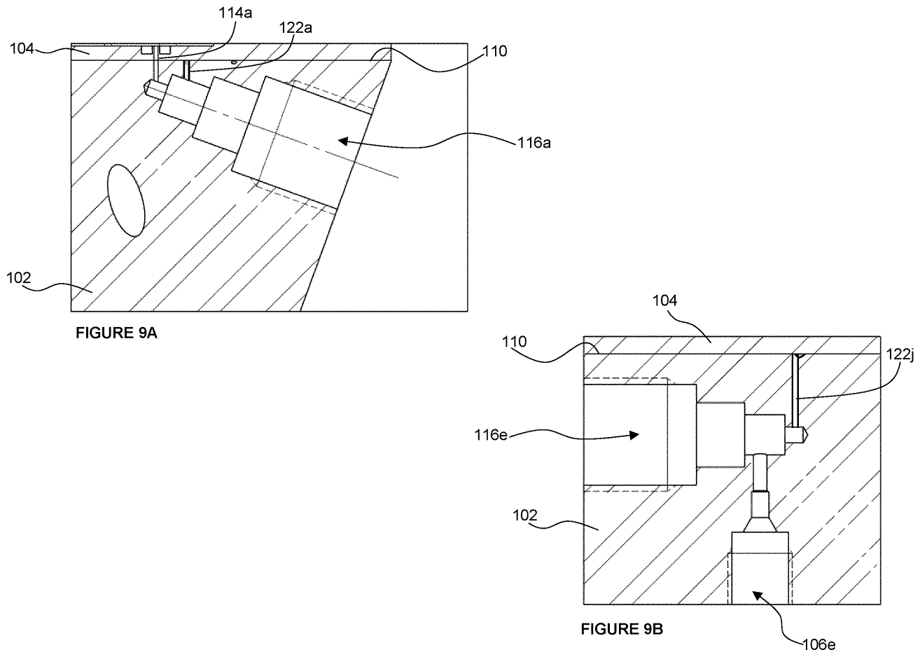

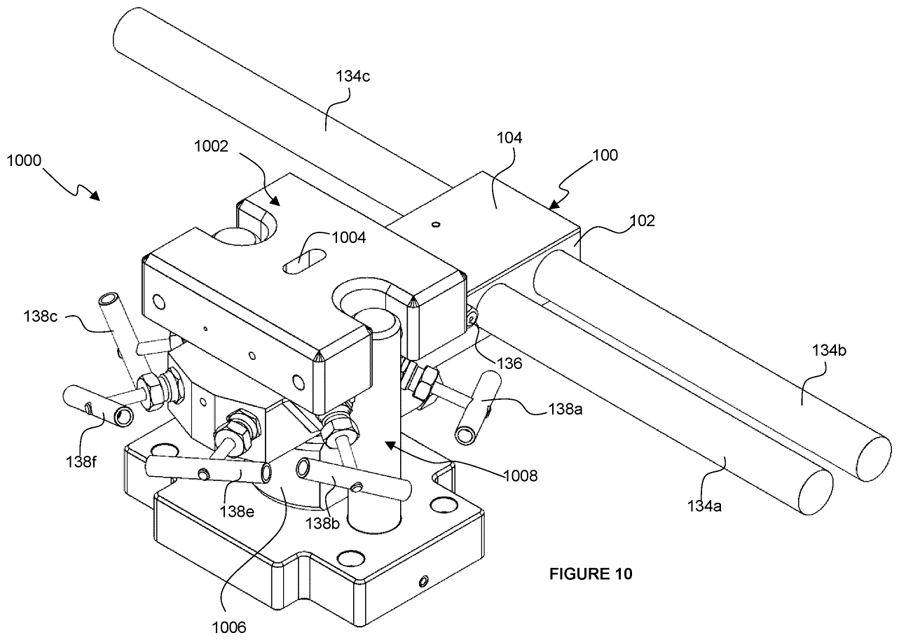

Referring still to FIG. 2, the valve ports 116a-f can then be formed into the first metallic block 102 (e.g. by machining), such that the first conduit 114a (not labelled in FIG. 2) and the first fluid inlet/outlet port 106a are in fluid communication via the first valve port 116a, the second conduit 114b (not labelled in FIG. 2) and the second fluid inlet/outlet port 106b are in fluid communication via the second valve port 116b, and so on. The configuration of the first valve port 116a is shown in more detail in FIG. 9A. The first valve port 116a fluidly connects the bore 122a and the first conduit 114a, such that the first fluid inlet/outlet port 106a (not visible in FIG. 9A) is in fluid communication with the first conduit 114a via the first channel 108a (not visible in FIG. 9A), the bore 122a, and the first valve port 116a. The second through fourth valve ports 116a-c are of a similar configuration. The configuration of the fifth valve port 116e is shown in FIG. 9B. The fifth valve port 116e fluidly connects the fifth fluid inlet/outlet port 106e (shown in FIG. 2) and the bore 122j. The sixth valve port 116f is of a similar configuration. In other words, while the first through fourth valve ports 116a-d are proximate the conduits 114a-d, the fifth and sixth valve ports 116e-f are proximate the fifth and sixth fluid inlet/outlet ports 106e-f.

As shown in FIG. 8, in use, valves 138a-f (i.e. a first valve 138a, a second valve 138b, and so on) may be received in each respective valve port 116a-f (not labelled in FIG. 8). In use, the valves 138a-f may be moveable to allow or prevent flow through the base 100. For example, the first valve 138a may be received in the first valve port 116a, and may be moveable between an open configuration in which the first conduit 114a and the first fluid inlet/outlet port 106a are in fluid communication via the first valve port 116a, and a closed configuration in which fluid communication between the first conduit 114a and the first fluid inlet/outlet port 106a is prevented.

As mentioned above, the base 100 can have a relatively low a low dead space. That is, in use, when the microfluidic chip 10 is seated against the second metallic block 104 and when the valves 138a-f are in the closed configuration, a dead space is defined in the base 100 between each valve 138a-f and the microfluidic chip 10. The dead space may have a volume of, for example, less than about 10 microliters, or less than about 5 microlitres (e.g. about 3.5 microlitres).

Referring back to FIG. 2, a plurality of heating cartridge receptacles 140a-f may then be formed in the first metallic block 102 (e.g. by machining). Heating cartridges (not shown) may be received in the heating cartridge receptacles 140a-f, in order to control the temperature of the base in use.

After bonding together the first metallic block 102 and second metallic block 104, the machining steps can be carried out in any order. That is, while the machining steps (e.g. the forming of the conduits 114a-f, the fluid inlet/outlet ports 106a-f, the valve ports 116a-f, the instrument ports 118a-c, and the heating cartridge receptacles 140a-f) are preferably carried out after bonding together the first metallic block 102 and the second metallic block 104 (in order to avoid deformation of these features during the bonding step), the various features can be machined into the first metallic block 102 and second metallic block 104 in any order (e.g. the valve ports 116a-f can be machined into the first metallic block 102 prior to machining the conduits 114a-f through the second metallic block 104).

In the example shown, the base 100 includes two layers (i.e. the first metallic block 102 and the second metallic block 104). In alternative examples, the base may include additional layers, which may include additional channels formed into the surface thereof. For example (not shown), the base can further include a third metallic block having a plurality of additional channels formed into a first surface thereof. Each additional channel can be in fluid communication with a respective fluid inlet/outlet port of the third metallic block. The first metallic block can overlie and be bonded to the first surface of the third metallic block, to cover the plurality of additional channels. The first metallic block can have a plurality of additional conduits that extend therethrough towards the third metallic block, for providing fluid communication between the microfluidic chip and the plurality of additional channels.

In the example shown, the base 100 includes valve ports 116a-f as well as fluid inlet/outlet ports 106a-f, In alternative examples, a port may be provided that serves as both a valve port and a fluid inlet/outlet port. For example, a flow-through valve may be received in one of the ports, and a fluid line may be connected to the flow-through valve. Such valves are described in International Patent Application No. PCT/CA2023/050448 (O'Brien et al.), which is incorporated herein by reference.

Referring now to FIG. 10, the base 100 is shown assembled into an example manifold 1000. The microfluidic chip 10 (not visible in FIG. 10) is seated against the base 100. The manifold 1000 further includes a cover 1002 that is positioned over the microfluidic chip 10 and that allows for optical access to the microfluidic chip 10 via a viewing window 1004 thereof; a jack 1006 for forcing the base 100 and the cover 1002 together with the microfluidic chip 10 sandwiched therebetween, to cause the cover to bear against the microfluidic chip and seal the microfluidic chip 10 to the base 100 (by compressing seals (not visible in FIG. 10) received in the annular recesses 132a-d of the base 100), and to apply a confining pressure to the microfluidic chip 10; and a support assembly 1008 for supporting the base 100, the cover 1002, and the jack 1006 and for guiding the motion of the base 100. The operation of such a manifold is described in International Patent Application Publication No. WO2022/251951 (de Haas et al.), which is incorporated herein by reference in its entirety.

In an alternative example, the base 100 may include the viewing window.

In further alternative examples, the base 100 may be assembled into another manifold.

While the above description provides examples of one or more processes or apparatuses or compositions, it will be appreciated that other processes or apparatuses or compositions may be within the scope of the accompanying claims.

To the extent any amendments, characterizations, or other assertions previously made (in this or in any related patent applications or patents, including any parent, sibling, or child) with respect to any art, prior or otherwise, could be construed as a disclaimer of any subject matter supported by the present disclosure of this application, Applicant hereby rescinds and retracts such disclaimer. Applicant also respectfully submits that any prior art previously considered in any related patent applications or patents, including any parent, sibling, or child, may need to be re-visited.

1. A base for a microfluidic manifold, the base comprising:
a first metallic block having a plurality of channels formed into a first surface thereof, wherein each channel is in fluid communication with a respective fluid inlet/outlet port of the first metallic block; and
a second metallic block against which a microfluidic chip is seatable, wherein the second metallic block overlies and is bonded to the first surface of the first metallic block to cover the plurality of channels, and wherein the second metallic block has a plurality of conduits that extend therethrough towards the first metallic block, for providing fluid communication between the microfluidic chip and the plurality of channels.

2. The base of claim 1, wherein the first metallic block further comprises at least a first valve port that provides fluid communication between a first one of the conduits and a first one of the fluid inlet/outlet ports.

3. The base of claim 2, further comprising a first valve received in the first valve port, wherein the first valve is moveable between an open configuration in which the first one of the conduits and the first one of the fluid inlet/outlet ports are in fluid communication via the first valve port, and a closed configuration in which fluid communication between the first one of the conduits and the first one of the fluid inlet/outlet ports is prevented.

4. The base of claim 3, wherein when the microfluidic chip is seated against the second metallic block and the first valve is in the closed configuration, a dead space is defined in the base between the valve and the microfluidic chip, and wherein the dead space has a volume of at most 10 microlitres.

5. (canceled)

6. The base of claim 1, wherein the first metallic block further comprises at least a first instrument port, wherein the first instrument port is in fluid communication with a first one of the channels.

7. The base of 5 further comprising a first instrument received in the first instrument port, wherein the first instrument comprises a pressure sensor, a viscosity sensor, and/or a density sensor.

8. (canceled)

9. (canceled)

10. (canceled)

11. (canceled)

12. (canceled)

13. (canceled)

14. The base of claim 1, wherein the first metallic block is a relatively thick block, and the second metallic block is a relatively thin platelet.

15. The base of claim 1, wherein
the base further comprises a third metallic block having a plurality of additional channels formed into a first surface thereof, and each additional channel is in fluid communication with a respective fluid inlet/outlet port of the third metallic block;
the first metallic block overlies and is bonded to the first surface of the third metallic block to cover the plurality of additional channels; and
the first metallic block has a plurality of additional conduits that extend therethrough towards the third metallic block, for providing fluid communication between the microfluidic chip and the plurality of additional channels.

16. A microfluidic manifold assembly comprising:
a microfluidic chip having a plurality of microfluidic inlet/outlet ports and at least a first microfluidic channel that is in fluid communication with the plurality of microfluidic inlet/outlet ports;
a base having (i) a first metallic block having a plurality of channels formed into a first surface thereof, wherein each channel is in fluid communication with a respective fluid inlet/outlet port of the first metallic block; and (ii) a second metallic block against which the microfluidic chip is seated, wherein the second metallic block overlies and is bonded to the first surface of the first metallic block to cover the plurality of channels, and wherein the second metallic block has a plurality of conduits extending therethrough towards the first metallic block, for providing fluid communication between the microfluidic inlet/outlet ports and the plurality of channels; and
a cover positioned over the microfluidic chip and bearing against the microfluidic chip to sandwich the microfluidic chip between the base and the cover.

17. The microfluidic manifold assembly of claim 16, further comprising at least a first seal, wherein the microfluidic chip is seated against the second metallic block via the first seal, and wherein the first seal is configured to seal at least a first one of the microfluidic inlet/outlet ports to a first one of the conduits.

18. The microfluidic manifold assembly of claim 16, further comprising a plurality of fluid lines mounted to the first metallic block, wherein each fluid line is in fluid communication with a respective one of the fluid inlet/outlet ports, for delivering fluid to and/or from the microfluidic chip via the base.

19. The microfluidic manifold assembly of claim 16,
wherein the first metallic block further comprises at least a first valve port, and the base further comprises a first valve received in the first valve port; and
wherein the valve is moveable between an open configuration in which a first one of the conduits and a first one of the fluid inlet/outlet ports are in fluid communication via the first valve port, and a closed configuration in which fluid communication between the first one of the conduits and the first one of the fluid inlet/outlet ports is prevented.

20. (canceled)

21. (canceled)

22. (canceled)

23. (canceled)

24. (canceled)

25. (canceled)

26. (canceled)

27. (canceled)

28. (canceled)

29. The microfluidic manifold assembly of claim 16, wherein
the base further comprises a third metallic block having a plurality of additional channels formed into a first surface thereof, and each additional channel is in fluid communication with a respective fluid inlet/outlet port of the third metallic block;
the first metallic block overlies and is bonded to the first surface of the third metallic block to cover the plurality of additional channels; and
the first metallic block has a plurality of additional conduits that extend therethrough towards the third metallic block, for providing fluid communication between the microfluidic chip and the plurality of additional channels.

30. A method of manufacturing a base for a microfluidic manifold, the method comprising:
a. forming a plurality of channels into a first surface of a first metallic block;
b. after step a., bonding a second metallic block to the first surface to cover the plurality of channels;
c. forming a plurality of conduits through the second metallic block, whereby the plurality of conduits are in fluid communication with the plurality of channels; and
d. forming a plurality of fluid inlet/outlet ports in the first metallic block, whereby the plurality of fluid inlet/outlet ports are in fluid communication with the plurality of channels.

31. The method of claim 30, wherein step a. comprises ball milling the plurality of channels into the first surface of the first metallic block, or acid etching the plurality of channels into the first surface of the first metallic block.

32. (canceled)

33. The method of claim 30, wherein step b. comprises diffusion bonding the second metallic block to the first metallic block.

34. The method of claim 30, wherein step c. comprises machining the plurality of conduits into the second metallic block, and/or step d. comprises machining the fluid inlet/outlet ports into the first metallic block.

35. (canceled)

36. The method of claim 30, wherein step c. and step d. are carried out after step b.

37. The method claim 30, further comprising forming at least a first valve port in the first metallic block, whereby a first one of the conduits and a first one of the fluid inlet/outlet ports are in fluid communication via the first valve port, and/or forming at least a first instrument port in the first metallic block, whereby the first instrument port is in fluid communication with the first channel.

38. (canceled)

39. The method of 14, further comprising bonding a third metallic block to the first metallic block, wherein the third metallic block has a plurality of additional channels formed into a first surface thereof and each additional channel is in fluid communication with a respective fluid inlet/outlet port of the third metallic block, wherein the first metallic block is bonded to the third metallic block to cover the plurality of additional channels, and wherein the first metallic block has a plurality of additional conduits that extend therethrough towards the third metallic block, for providing fluid communication between the microfluidic chip and the plurality of additional channels.
